(19) United States
(12) Patent Application Publication
(10) Pub. No.: US 2026/0175897 A1
(43) Pub. Date: Jun. 25, 2026

(54) STEERING APPARATUS

(71) Applicant: Honda Motor Co., Ltd., Tokyo (JP)

(72) Inventor: Ryo Kawaguchi, Tokyo (JP)

(21) Appl. No.: 19/430,015

(22) Filed: Dec. 22, 2025

(30) Foreign Application Priority Data
Dec. 24, 2024 (JP) 2024-227042

(51) Int. Cl. B62D 1/04; B62D 1/06; B62D 1/08; B62D 1/10; B62D 6/00; H03K 17/96

(52) U.S. Cl. CPC B62D 1/046; B62D 1/06; B62D 1/08; B62D 1/10; B62D 6/00; H03K 17/9622; H03K 2017/9606

(57) ABSTRACT

A steering apparatus including a steering wheel and a non-contact sensor part provided on a hub portion or spoke portion to detect a grip operation of a rim portion by an occupant. The rim portion includes an upper and lower horizontal rim portions extending substantially horizontally, and a pair of left and right vertical rim portions connecting left and right end portions of the upper and lower horizontal rim portions, and the vertical rim portion includes a first vertical rim portion below the spoke portion and a second vertical rim portion above the spoke portion. The second vertical rim portion extends in a substantially vertical direction from the spoke portion to the upper horizontal rim portion, and an angle of the second vertical rim portion with respect to a horizontal line is equal to or larger than a predetermined angle.

### CROSS-REFERENCE TO RELATED APPLICATION

This application is based upon and claims the benefit of priority from Japanese Patent Application No. 2024-227042 filed on Dec. 24, 2024, the content of which is incorporated herein by reference.

### BACKGROUND OF THE INVENTION

### Field of the Invention

This invention relates to a steering apparatus capable of detecting a gripping state of a steering wheel.

### Description of the Related Art

In recent years, efforts to provide access to sustainable transportation systems that consider people in vulnerable positions among traffic participants have been intensifying. To achieve this, research and development on driving support technology is being conducted. Against this backdrop, there has been a known apparatus which includes a grip sensor on the rim of the steering wheel to detect the grip state of the rim by the driver. Such an apparatus is described in, for example, Japanese Unexamined Patent Publication No. 2023-172312 (JP 2023-172312 A).

JP 2023-172312 A describes a non-circular, irregularly shaped steering wheel. The steering wheel described in JP 2023-172312 A has a pair of left and right grips below a pair of left and right spoke portions, and grip sensors are provided on the pair of grips.

In a steering apparatus with such an irregularly shaped steering wheel, it is preferable to expand the grip area of the steering wheel not only below but also above the spoke portions to enhance operability. However, expanding the grip area of the steering wheel increases the number and installation area of sensors for detecting the grip state, leading to increased costs.

### SUMMARY OF THE INVENTION

An aspect of the present invention is a steering apparatus including: a steering wheel including a hub portion connected to a steering shaft, a rim portion extending around the hub portion over an entire circumference in a circumferential direction centered on the hub portion so as to be gripped by an occupant, and a spoke portion extending in a left-right direction from the hub portion to connect the hub portion and the rim portion; and a sensor part of a non-contact type provided on the hub portion or the spoke portion so as to detect a grip operation of the rim portion by the occupant. The rim portion includes an upper horizontal rim portion and a lower horizontal rim portion extending substantially horizontally above and below the hub portion, respectively, and a pair of left and right vertical rim portions connecting left and right end portions in the left-right direction of the upper horizontal rim portion and left and right end portions in the left-right direction of the lower horizontal rim portion, a distance from the hub portion to the upper horizontal rim portion is longer than a distance from the hub portion to the lower horizontal rim portion, the pair of left and right vertical rim portions each includes a first vertical rim portion located below the spoke portion and a second vertical rim portion located above the spoke portion, and the second vertical rim portion extends in a substantially vertical direction from the spoke portion to the upper horizontal rim portion in a neutral state where the steering wheel is not steered, and an angle of the second vertical rim portion with respect to a horizontal line is equal to or larger than a predetermined angle.

### BRIEF DESCRIPTION OF THE DRAWINGS

The objects, features, and advantages of the present invention will become clearer from the following description of embodiments in relation to the attached drawings, in which:

FIG. 1 is a side view illustrating a schematic configuration in the vicinity of a driver's seat of a vehicle including a steering apparatus according to an embodiment of the present invention;

FIG. 2 is a view taken along arrow II in FIG. 1;

FIG. 3 is a view illustrating a part of a steering wheel of FIG. 2;

FIG. 4A is an enlarged view of a main part of FIG. 3;

FIG. 4B is a cross-sectional view taken along line B-B of FIG. 4A;

FIG. 5 is a diagram illustrating a principle of a torque sensor;

FIG. 6A is a block diagram illustrating a control configuration of the steering apparatus according to the embodiment of the present invention;

FIG. 6B is a block diagram illustrating a control configuration of a self-drive system; and

FIG. 7 is a flowchart illustrating an example of processing executed by a controller of FIG. 6A.

### DETAILED DESCRIPTION OF THE INVENTION

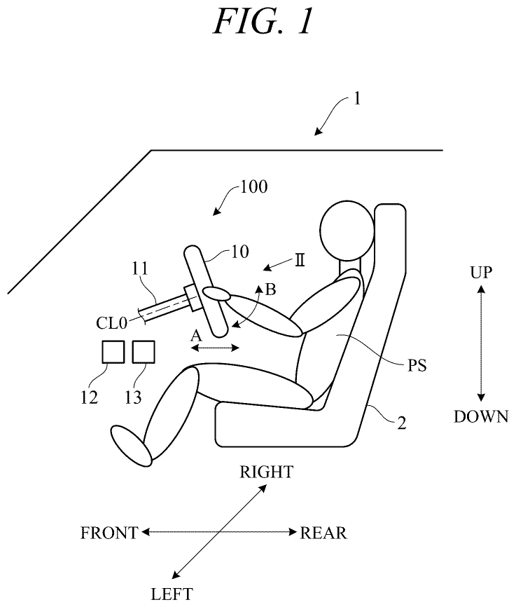

Hereinafter, embodiments of the present invention will be described with reference to FIGS. 1 to 7. A steering apparatus according to an embodiment of the present invention is mounted on a vehicle. The vehicle is, for example, a self-driving vehicle having a self-driving capability that does not require a driving operation by a driver. The vehicle may be a manually driven vehicle that requires a driving operation by a driver. Hereinafter, an example in which the steering apparatus is applied to a self-driving vehicle will be described. The self-driving vehicle is configured to be capable of switching a drive mode from a self-drive mode in which a driving operation by the driver is unnecessary to a manual drive mode in which the driving operation by the driver is necessary.

FIG. 1 is a side view illustrating a schematic configuration in the vicinity of a driver's seat of a vehicle 1 including a steering apparatus 100 according to the embodiment of the present invention. Hereinafter, a front-rear direction, a left-right direction, and an up-down direction are defined as illustrated in the drawing, and the configuration of each unit will be described in accordance with such definitions. The front-rear direction, the left-right direction, and the up-down direction correspond to the front-rear direction (length direction), the left-right direction (width direction), and the up-down direction (height direction) of the vehicle 1.

FIG. 1 illustrates a state where an occupant PS is seated in a driver's seat 2 of the vehicle 1. As illustrated in FIG. 1, the steering apparatus 100 includes a steering wheel 10 disposed facing the driver's seat 2 and operated by the occupant PS. The steering wheel 10 is supported by a front end portion (rear end portion) of a steering shaft 11 extending, with an upward inclination, along a center line CL0 from the front to the rear of the vehicle. The steering shaft 11 rotates integrally with the steering wheel 10 according to the operation of the steering wheel 10.

Although not illustrated in detail, the steering apparatus 100 includes a telescopic mechanism 12 and a tilt mechanism 13. The steering wheel 10 can be moved in the front-rear direction (a direction of arrow A in FIG. 1) by the telescopic mechanism 12, and can be moved in the up-down direction by the tilt mechanism 13. Accordingly, the occupant PS can move the steering wheel 10 to an arbitrary position. The telescopic mechanism 12 and the tilt mechanism 13 are driven by manual operation of the occupant. At least one of the telescopic mechanism 12 or the tilt mechanism 13 may be driven by an actuator (for example, an electric motor).

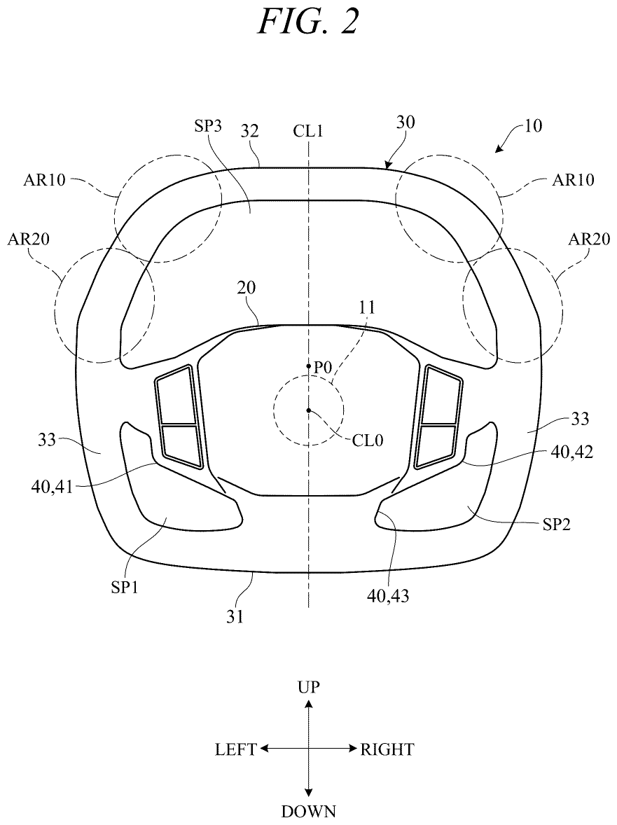

FIG. 2 is a front view of the steering wheel 10 in a neutral state (view taken along arrow II in FIG. 1). The neutral state is a state where the steering wheel 10 is not steered, and is a state where the vehicle travels straight. As illustrated in FIG. 2, the steering wheel 10 includes a hub portion 20 connected to the steering shaft 11, a rim portion 30 disposed around the hub portion 20 so as to surround the hub portion 20, and a spoke portion 40 connecting the hub portion 20 and the rim portion 30. The rim portion 30 is gripped by the occupant PS, and the steering wheel 10 is rotated about the center line CL0.

The center line CL0 passes through the central portion of the hub portion 20 (for example, the center of the hub portion 20), and the steering wheel 10 extends along a plane perpendicular to the center line CL0. The steering wheel 10 is configured to be symmetrical with respect to a center line CL1 extending in the up-down direction through the center line CL0. Hereinafter, a direction away from the center line CL0 is referred to as a lateral outward direction or a lateral outside, and a direction toward the center line CL0 is referred to as a lateral inward direction or a lateral inside.

The entire rim portion 30 is non-circular, and the steering wheel 10 is configured as a deformed steering wheel. More specifically, the rim portion 30 includes a lower rim portion 31 extending in the left-right direction below the hub portion 20, an upper rim portion 32 extending in the left-right direction above the hub portion 20, and a pair of left and right vertical rim portions 33 and 33 respectively extending substantially in the up-down direction on the right and left sides of the hub portion 20 and connecting both end portions in the left-right direction of the lower rim portion 31 and both end portions in the left-right direction of the upper rim portion 32. By the lower rim portion 31, the upper rim portion 32, and the pair of left and right vertical rim portions 33 and 33, the rim portion 30 has a substantially rectangular shape or a substantially D-shape as a whole.

A distance from the hub portion 20 (for example, the center line CL0) to the lower rim portion 31 is shorter than a distance from the hub portion 20 to the upper rim portion 32. Therefore, the hub portion 20 is positioned below the center of the steering wheel 10 (a center PO of the rim portion 30). The spoke portion 40 includes a left spoke portion 41 extending leftward from the hub portion 20, a right spoke portion 42 extending rightward, and a lower spoke portion 43 extending downward, and is configured as three spokes. Accordingly, a substantially donut-shaped space between the hub portion 20 and the rim portion 30 is divided into three via the spoke portion 40. That is, the space is divided into a lower left space SP1, a lower right space SP2, and an upper space SP3 of the hub portion 20. The number of the spoke portions 40 may be 2 or 4, and the configuration of the spoke portions 40 is not limited to that illustrated in the drawings. For example, the spoke portions 40 may be the left spoke portion 41 and the right spoke portion 42. Hereinafter, the pair of left and right spoke portions 41 and 42 may be referred to as spoke portions 40.

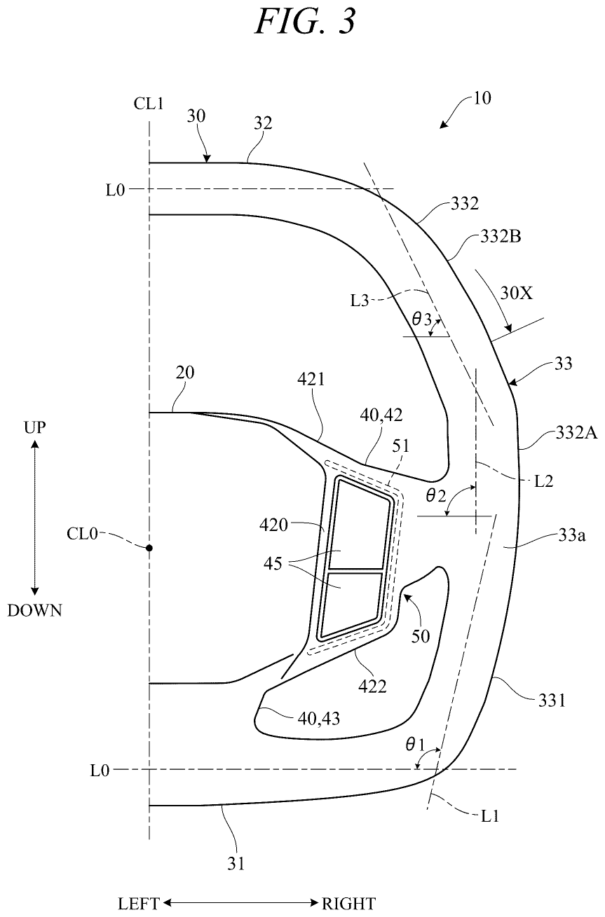

The configuration of the rim portion 30 will be described in more detail. FIG. 3 is a front view illustrating a configuration of the steering wheel 10 on the right side of the center line CL1. As illustrated in FIG. 3, in the vertical rim portion 33, a portion below a connection portion 33a to which the right spoke portion 42 is connected is referred to as a lower vertical rim portion 331, and a portion above a connection portion 30a is referred to as an upper vertical rim portion 332.

The lower rim portion 31 and the upper rim portion 32 each extends along a horizontal line L0. The lower vertical rim portion 331 extends, in an inclined manner, upward from the right end portion (lateral outer end portion) of the lower rim portion 31, strictly upward and slightly rightward (lateral outward direction). That is, the lower vertical rim portion 331 extends along a straight line L1 extending upward and slightly rightward. Therefore, an angle θ1 formed by the lower rim portion 31 and the lower vertical rim portion 331 (an angle formed by the horizontal line L0 and the straight line L1) is larger than 90 degrees by a predetermined angle (for example, about 5 degrees to 15 degrees). A connection portion between the lower rim portion 31 and the lower vertical rim portion 331 is formed in a smooth curved surface shape.

The upper vertical rim portion 332 has a lower-side upper vertical rim portion 332A extending upward from a connection portion 33a between the right spoke portion 42 and the vertical rim portion 33, and an upper-side upper vertical rim portion 332B extending upward and leftward from the upper end portion of the lower-side upper vertical rim portion 332A. In other words, the upper vertical rim portion 332 has the lower-side upper vertical rim portion 332A extending along a straight line L2 extending in the vertical direction, and the upper-side upper vertical rim portion 332B extending along a straight line L3 extending upward and leftward.

An angle θ2 formed by the lower-side upper vertical rim portion 332A with respect to a horizontal line is 90 degrees or about 90 degrees, and the lower-side upper vertical rim portion 332A rises more rapidly than the lower vertical rim portion 331. An angle θ3 formed by the upper-side upper vertical rim portion 332B with respect to the horizontal line is smaller than 02. Specifically, the angle θ3 is larger than 45 degrees, for example, about 60 degrees to 80 degrees. A connection portion between the lower-side upper vertical rim portion 332A and the upper-side upper vertical rim portion 332B and a connection portion between the upper-side upper vertical rim portion 332B and the upper rim portion 32 are formed in a smooth curved surface shape. The entire portion from the connection portion 33a to the right end portion of the upper rim portion 32 may be formed in a smooth curved surface shape.

The right spoke portion 42 has an enlarged portion 420 in which a length (width) in the up-down direction is enlarged toward the left (lateral inward direction). An upper edge 421 of the enlarged portion 420 extends, in an inclined manner, obliquely upward and toward the left, and a lower edge 422 of the right spoke portion 42 extends, in an inclined manner, obliquely downward and toward the left. The length in the up-down direction of the enlarged portion 420 is longer than the length in the left-right direction, and the enlarged portion 420 is formed to be long in the up-down direction. A pair of upper and lower switches 45 (steering switches) is disposed in the enlarged portion 420. The switch 45 is a toggle switch or a press-type switch. The driver can operate (for example, operate with a thumb) the switch 45 while gripping the rim portion 30.

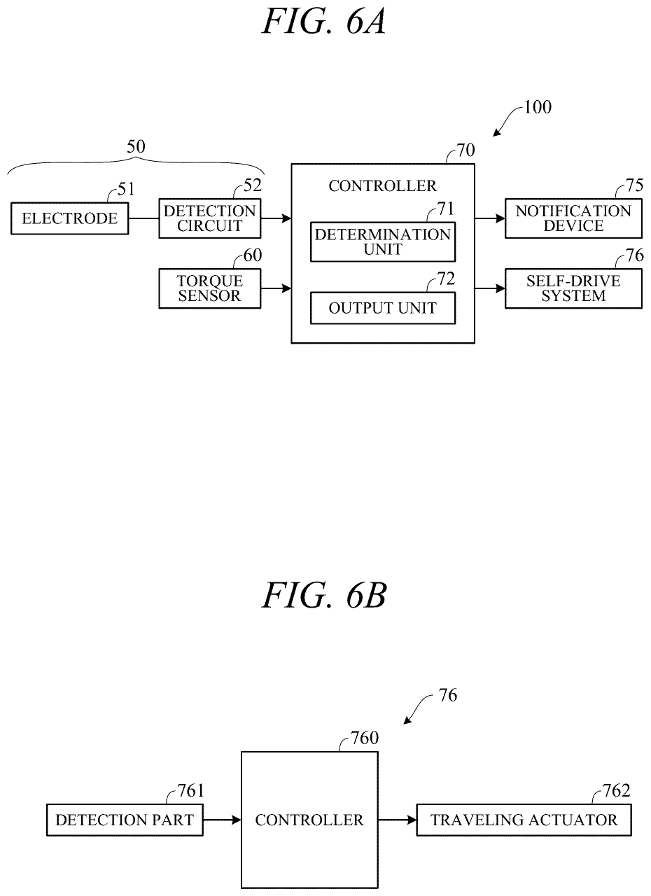

The steering apparatus 100 according to the present embodiment includes a grip sensor 50 of electrostatic capacitance type for detecting a grip operation of the driver gripping the rim portion 30. The grip sensor 50 includes a power source (not illustrated), an electrode 51 disposed in the enlarged portion 420, and a detection circuit 52 (FIG. 6A) that detects electrostatic capacitance of the electrode 51 or a change in the electrostatic capacitance. The detection circuit 52 detects, for example, an electrical characteristic of the electrode 51, that is, the magnitude of electrostatic capacitance between the electrode 51 and the ground (vehicle body). The electrostatic capacitance detected by the detection circuit 52 increases as a detection target (the occupant's body) approaches the electrode 51, and decreases as the detection target moves away from the electrode.

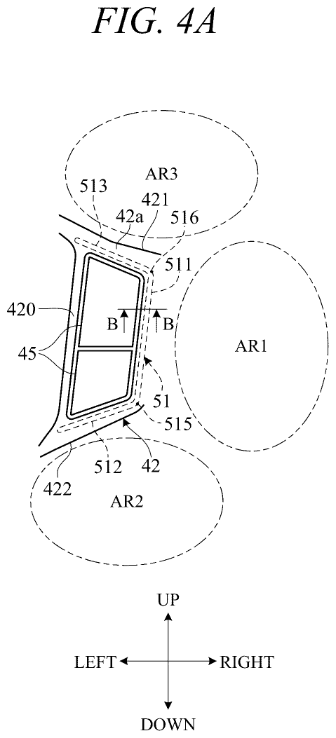

FIG. 4A is an enlarged view of a main part of FIG. 3 illustrating arrangement of the electrode 51, and FIG. 4B is a cross-sectional view taken along line B-B of FIG. 4A. As illustrated in FIG. 4A, the electrode 51 is housed inside the enlarged portion 420 of the right spoke portion 42. Therefore, the electrode 51 is covered by a surface 42a of the right spoke portion 42 facing the driver without being exposed. The electrode 51 is formed by bending a plate-like member having conductivity, and is disposed around the switch 45 so as not to interfere with the switch 45.

More specifically, the electrode 51 includes a central electrode portion 511 extending in the up-down direction on the right side of the switch 45, a lower electrode portion 512 extending, in an inclined manner, leftward and downward from the lower end portion of the central electrode portion 511, and an upper electrode portion 513 extending, in an inclined manner, leftward and upward from the upper end portion of the central electrode portion 511. The lower electrode portion 512 extends substantially parallel to the lower edge 422 along the lower edge 422 of the right spoke portion 42. The upper electrode portion 513 extends substantially parallel to the upper edge 421 along the upper edge 421 of the right spoke portion 42.

As illustrated in FIG. 4B, the electrode 51 includes a pair of electrode layers (an inner electrode layer 51a and an outer electrode layer 51b) each having a substantially thin plate shape, and an insulating layer 51c interposed between the pair of electrode layers 51a and 51b. The inner electrode layer 51a is disposed to face the switch 45 (FIG. 4A). The end portion of the inner electrode layer 51a and the end portion of the outer electrode layer 51b are at least partially connected via a connection portion 51d (dotted line), and are bent at the connection portion 51d to form the electrode 51.

As illustrated in FIG. 4A, insulating portions 515 and 516 that insulate the electrode portions from each other are provided at a boundary portion between the central electrode portion 511 and the lower electrode portion 512 and at a boundary between the central electrode portion 511 and the upper electrode portion 513, respectively. Accordingly, the electrode 51 is electrically divided into three corresponding to the electrode portions 511 to 513 via the insulating portions 515 and 516. Therefore, the grip operation of an area AR1 can be detected by the central electrode portion 511, the grip operation of an area AR2 can be detected by the lower electrode portion 512, and the grip operation of an area AR3 can be detected by the upper electrode portion 513. The area AR1 includes the connection portion 33a of FIG. 3 and an area in the vicinity thereof. The area AR2 includes the lower rim portion 31 and the lower vertical rim portion 331 of FIG. 3. The area AR3 includes the upper vertical rim portion 332 of FIG. 3. As a result, it is possible not only to determine whether or not the steering wheel 10 is gripped but also to identify the gripping area of the steering wheel 10.

The maximum distance from the electrode 51 which allows the grip operation of the steering wheel 10 to be detected is defined as a detectable distance. As illustrated in FIG. 3, in the present embodiment, the enlarged portion 420 is configured to be vertically long in the up-down direction. Therefore, the distance from the electrode 51 (lower electrode portion 512) in the vicinity of the lower edge 422 of the right spoke portion 42 to the lower vertical rim portion 331 facing the lower electrode portion 512 is less than or equal to the detectable distance. Accordingly, the grip operation of the lower vertical rim portion 331 can be detected by the grip sensor 50. In addition, since the central electrode portion 511 is disposed on the right side of the switch 45, the distance from electrode 51 (central electrode portion 511) to the connection portion 33a and the vicinity thereof is also less than or equal to a detectable distance. Accordingly, the grip sensor 50 can detect the grip operation in the vicinity of the connection portion 33a.

Furthermore, the distance from the electrode 51 (upper electrode portion 513) in the vicinity of the upper edge 421 of the right spoke portion 42 to the lower-side upper vertical rim portion 332A of the upper vertical rim portion 332 facing the upper electrode portion 513 is less than or equal to the detectable distance. Accordingly, the grip operation of the lower-side upper vertical rim portion 332A can be detected by the grip sensor 50.

On the other hand, the distance from the upper electrode portion 513 to the upper-side upper vertical rim portion 332B exceeds the detectable distance. Therefore, it is difficult for the grip sensor 50 to detect the grip operation of the upper vertical rim portion 332 (upper-side upper vertical rim portion 332B) above the right spoke portion 42 by a predetermined distance or more. The upper vertical rim portion 332 above the right spoke portion 42 by a predetermined distance or more, that is, the upper vertical rim portion 332 where it is difficult to detect the grip operation with the grip sensor 50 is referred to as an undetectable rim portion 30X (see FIG. 3) for convenience.

The undetectable rim portion 30X may include the upper portion or upper end portion of the lower-side upper vertical rim portion 332A. The lower portion or the lower end portion of the upper-side upper vertical rim portion 332B may be removed from the undetectable rim portion 30X. That is, the undetectable rim portion 30X may start from above or below the boundary portion, instead of starting from the boundary portion between the lower-side upper vertical rim portion 332A and the upper-side upper vertical rim portion 332B.

In the present embodiment, the lower-side upper vertical rim portion 332A extends in a substantially vertical direction along the straight line L2, and the upper-side upper vertical rim portion 332B extends, in an inclined manner, from the upper end portion of the lower-side upper vertical rim portion 332A so as to be inclined at the predetermined angle θ3 with respect to the horizontal line along the straight line L3. The predetermined angle θ3 is larger than 45 degrees, for example, 60 degrees or more. Therefore, the undetectable rim portion 30X is formed to rise from the horizontal line by the predetermined angle θ3 or more. Therefore, in a case where the occupant (driver) grips the undetectable rim portion 30X (for example, an area AR10 in FIG. 2), the occupant needs to grip the undetectable rim portion 30X with a relatively large grip strength against the own weight of the hand, which puts a heavy burden on the occupant.

Therefore, a time during which the occupant grips the undetectable rim portion 30X is short, and a frequency of gripping the undetectable rim portion 30X is reduced. As a result, the occupant grips the upper vertical rim portion 332 (lower-side upper vertical rim portion 332A) below the undetectable rim portion 30X while placing the hand on the spoke portion 40 below the undetectable rim portion 30X and supporting the hand on the spoke portion 40 (an area AR20 in FIG. 2). Accordingly, the grip sensor 50 can satisfactorily detect the grip operation of the rim portion 30 above the spoke portion 40 (42).

The occupant may grip the top portion (upper rim portion 32) of the rim portion 30. Since the distance from the electrode 51 to the top portion of the rim portion 30 exceeds the detectable distance, it is difficult for the grip sensor 50 to detect the grip operation of the top portion of the rim portion 30. Such a grip operation can be detected by a torque sensor provided on the steering shaft 11.

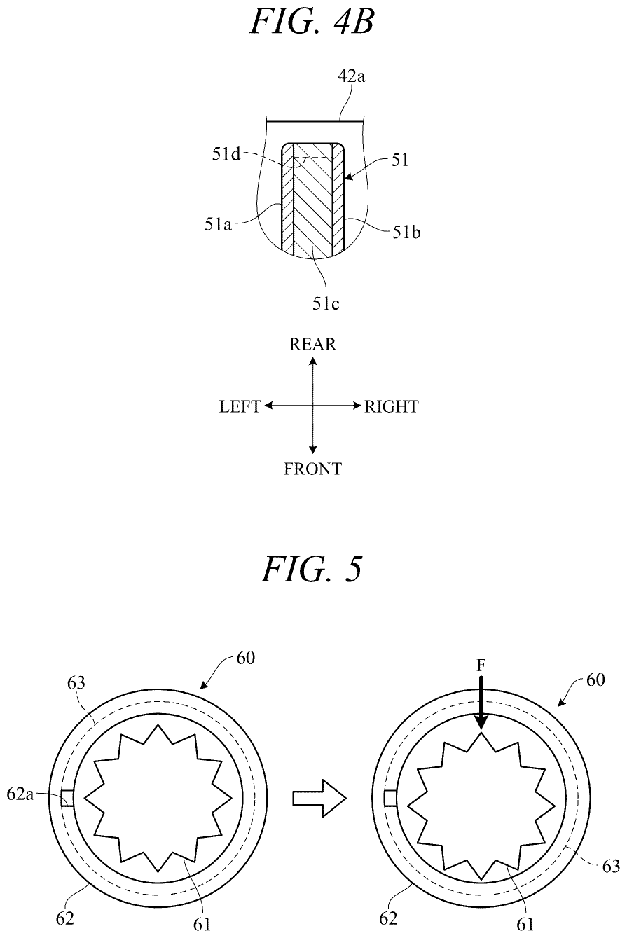

FIG. 5 is a diagram schematically illustrating a configuration of a main part of a torque sensor 60. As illustrated in FIG. 5, the torque sensor 60 includes a rotatable pinion 61 provided integrally with the steering shaft 11 and a sleeve 62 fixedly disposed at a predetermined position around the pinion 61. A coil 63 is wound around the sleeve 62, and a window 62a is opened in the sleeve 62. With the rotation of the steering shaft 11, the protrusion of the pinion 61 approaches or separates from the coil 63 via the window 62a, whereby a magnetic flux density changes. By reading the change in the magnetic flux density, the operation direction and the operation torque of the steering wheel 10 can be detected.

When an own weight F of the driver's hand acts on the top portion of the steering wheel 10, the steering shaft 11 is pushed downward, and the pinion 61 moves relatively downward with respect to the sleeve 62. Accordingly, a positional relationship between the protrusion of the pinion 61 and the coil 63 of the sleeve 62 changes, and the magnetic flux density changes. Taking this into account, it is determined whether or not the change in the magnetic flux density is larger than or equal to a predetermined threshold α1, and in a case where the change in the magnetic flux density is larger than or equal to the threshold α1, it is determined that the own weight has acted on the top portion of the steering wheel 10, that is, the top portion has been gripped. Accordingly, the grip operation of the top portion of the steering wheel 10 can be detected by the torque sensor 60.

The occupant may grip the bottom portion (lower rim portion 31) of the steering wheel 10. In this case, since the own weight of the hand acts on the bottom portion of the steering wheel 10, the relative position of the pinion 61 with respect to the sleeve 62 changes, and the magnetic flux density around the coil 63 changes as described above. Taking this into account, by determining whether or not the change in the magnetic flux density is larger than or equal to a predetermined threshold α2, the grip operation of the bottom portion of the steering wheel 10 can be detected by the torque sensor 60.

The downward load acting on the steering wheel 10 when the occupant grips the top portion of the steering wheel 10 is larger than the downward load acting when the occupant grips the bottom portion, and the change in the magnetic flux density is also larger. Therefore, the threshold α1 may be set to a value larger than the threshold α2. However, in the present embodiment, since the distance from the electrode 51 to the bottom portion of the steering wheel 10 is less than or equal to the detectable distance, the grip operation of the bottom portion can be detected by the grip sensor 50. In such a case, it is not necessary to detect the grip operation of the bottom portion of the steering wheel 10 by the torque sensor 60.

FIG. 6A is a block diagram illustrating a control configuration of the steering apparatus 100 according to the present embodiment. As illustrated in FIG. 6A, the steering apparatus 100 includes the grip sensor 50, the torque sensor 60, a controller 70, a notification device 75, and a self-drive system 76. The notification device 75 is a device for notifying the occupant of a grip command for gripping the steering wheel 10, and includes a speaker and a monitor.

Signals from the grip sensor 50 (detection circuit 52) and the torque sensor 60 are input to the controller 70. The controller 70 includes a computer including a CPU, a ROM, a RAM, and other peripheral circuits. The controller 70 has functions as a determination unit 71 and an output unit 72.

The determination unit 71 determines whether or not an electrostatic capacitance C, which has been detected through the detection circuit 52, is larger than or equal to a predetermined threshold Ca. When the electrostatic capacitance C is larger than or equal to the threshold Ca (C≥Ca), the determination unit 71 determines that steering wheel 10 is gripped. On the other hand, when the electrostatic capacitance C is less than threshold Ca (C<Ca), the determination unit 71 determines that the steering wheel 10 is not gripped. When C≥Ca, the determination unit 71 identifies which electrode portion 511 to 513 among the plurality of electrode portions 511 to 513 provides a signal for which it is determined that the electrostatic capacitance C is larger than or equal to the threshold Ca. Accordingly, the gripping areas AR1 to AR3 (FIG. 4A) of the steering wheel 10 can be identified.

When C<Ca, the determination unit 71 further determines whether or not the steering wheel 10 is gripped, based on a signal from torque sensor 60. Specifically, it is determined whether or not an output value (a change in magnetic flux density) a of the torque sensor 60 is larger than or equal to the predetermined threshold α1. When the output value α is larger than or equal to the threshold α1 (α≥α1), the determination unit 71 determines that the steering wheel 10 is gripped (for example, the top portion of the steering wheel 10 is gripped). On the other hand, when the output value α is less than the threshold α1 (α<α1), the determination unit 71 determines that the steering wheel 10 is not gripped. The determination unit 71 may determine whether or not the steering wheel 10 is gripped (for example, the bottom portion of the steering wheel 10 is gripped) by determining the relative magnitude of the output value α of the torque sensor 60 and the predetermined threshold α2 (<α1).

The output unit 72 outputs a determination result of the determination unit 71 to the notification device 75 and the self-drive system 76. In addition, the output unit 72 communicates with the self-drive system 76, and determines whether or not a grip command for gripping the steering wheel 10 is output from the self-drive system 76. Then, when the grip command is output from the self-drive system 76, a signal is output to the notification device 75 to notify the occupant that the occupant should grip the steering wheel 10.

For example, while the vehicle 1 is traveling in the self-drive mode, the self-drive system 76 determines whether or not it becomes necessary to switch the drive mode from the self-drive mode to the manual drive mode, based on the surroundings of the vehicle 1 and the condition of the vehicle itself. Then, when determining that it is necessary to switch from the self-drive mode to the manual drive mode (for example, when the automated driving level is changed from level 3 to level 2), the self-drive system 76 outputs, to the controller 70, the grip command for gripping the steering wheel 10.

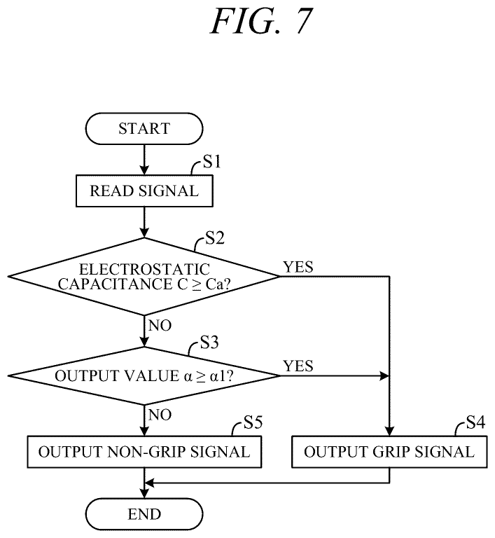

FIG. 6B is a block diagram illustrating a control configuration of the self-drive system 76. As illustrated in FIG. 6B, the self-drive system 76 includes a detection part (camera, LiDAR, radar, or the like) 761 that detects the surroundings of the vehicle 1, a traveling actuator (travel motor, brake actuator, steering actuator, or the like) 762, and a controller 760 that controls the traveling actuator 762 such that the vehicle 1 travels by self-driving, based on a detection result of the detection part 761. The controller 760 includes a computer including a CPU, a ROM, a RAM, and other peripheral circuits. FIG. 7 is a flowchart illustrating an example of processing executed by the CPU of the controller 70 according to a program stored in advance. The processing illustrated in the flowchart is started on condition that the grip command for gripping the steering wheel 10 is output from the self-drive system 76 while the vehicle 1 is traveling in the self-drive mode, that is, when the grip command for gripping the steering wheel 10 is notified from the notification device 75, and is repeated at a predetermined cycle. The processing illustrated in the flowchart may be started when the power switch of the vehicle 1 is turned on regardless of the presence or absence of the output of the grip command.

First, in S1 (S: processing step), the controller (CPU) 70 reads signals from the grip sensor 50 (detection circuit 52) and the torque sensor 60. Next, in S2, the controller 70 determines whether or not the electrostatic capacitance C, which has been detected by the grip sensor 50, is larger than or equal to the threshold Ca. When a negative determination is made in S2, the processing proceeds to S3, and when a positive determination is made, the processing proceeds to S4.

In S3, the controller 70 determines whether or not the output value α of the torque detected by the torque sensor 60 is larger than or equal to the threshold α1. When a positive determination is made in S3, the processing proceeds to S4, and when a negative determination is made in S3, the processing proceeds to S5. In S4, the controller 70 outputs a grip signal indicating that steering wheel 10 is gripped, to the notification device 75 and the self-drive system 76. Accordingly, the notification of the grip command for gripping the steering wheel 10 is stopped.

On the other hand, in S5, the controller 70 outputs a non-grip signal indicating that the steering wheel 10 is not gripped, to the notification device 75 and the self-drive system 76. While the non-grip signal is being output, the notification device 75 continuously notifies the grip command. When the grip signal is not output even though the notification device 75 has notified the grip command for a predetermined time (when the occupant does not grip the steering wheel 10), the self-drive system 76 executes a predetermined operation (for example, a stop operation) of the vehicle 1.

The operation of the steering apparatus 100 according to the present embodiment is summarized as follows. While traveling in the self-drive mode, when it becomes necessary to switch the drive mode to the manual drive mode, the notification device 75 notifies the grip command for gripping the steering wheel 10. Accordingly, the occupant (driver) grips the steering wheel 10. The distance from the electrode 51 to the lower rim portion 31 and the lower vertical rim portion 331, the distance from the electrode 51 to the vicinity of the connection portion 33a where the spoke portion 40 and the rim portion 30 intersect, and the distance from the electrode 51 to the lower-side upper vertical rim portion 332A in the upper vertical rim portion 332 are all less than or equal to the detectable distance of the grip sensor 50. Therefore, when the occupant grips these portions, the grip sensor 50 detects the grip operation.

On the other hand, the distance from the electrode 51 to the upper-side upper vertical rim portion 332B in the upper vertical rim portion 332 exceeds the detectable area. Therefore, in a case where the upper-side upper vertical rim portion 332B is gripped, it is difficult for the grip sensor 50 to detect the grip operation. However, the upper-side upper vertical rim portion 332B rises at the predetermined angle θ3 (for example, 60 degrees or more) with respect to the horizontal line. For this reason, when gripping the upper-side upper vertical rim portion 332B, the occupant needs to grip the upper-side upper vertical rim portion against the own weight of the hand, and a burden is large for the occupant. As described above, by configuring the upper-side upper vertical rim portion 332B (undetectable rim portion 30X) to be difficult for the occupant to grip, the time during which the occupant grips the upper-side upper vertical rim portion 332B is shortened, and the frequency of gripping the upper-side upper vertical rim portion 332B is also reduced. As a result, the occupant grips the rim portion 30 in the area detectable by the grip sensor 50 below the upper-side upper vertical rim portion 332B, and can satisfactorily detect the grip operation of the rim portion 30.

When the occupant grips the top portion of the steering wheel 10, the output value α of the torque sensor 60 exceeds the threshold α1. Therefore, even in a case where the top portion of the steering wheel 10 that cannot be detected by the grip sensor 50 is gripped, the grip operation can be satisfactorily detected by the torque sensor 60. Even in a case where the grip sensor 50 fails, the grip operation of the rim portion 30 can be detected on the basis of the output value of the torque sensor 60.

The controller 760 in FIG. 6B may be included in the controller 70 in FIG. 6A. In this case, signals from the grip sensor 50, the torque sensor 60, and the detection part 761 are input to the controller 70. The controller 70 executes predetermined processing on the basis of these input signals, and outputs control signals to the notification device 75 and the traveling actuator 762.

According to the present embodiment, the following functions and effects are achievable.

(1) The steering apparatus 100 includes: the steering wheel 10, that is, the steering wheel 10 that includes the hub portion 20 connected to the steering shaft 11, the rim portion 30 that extends around the hub portion 20 over the entire circumference in a circumferential direction with the hub portion 20 as a center and is gripped by an occupant, and the spoke portion 40 (41, 42) that extends in the left-right direction from the hub portion 20 and connects the hub portion 20 and the rim portion 30; and the non-contact grip sensor 50 that is provided on the spoke portions 40 so as to detect a grip operation of the rim portion 30 by the occupant (FIGS. 2 and 3). The rim portion 30 includes the upper rim portion 32 and the lower rim portion 31 that extend in a substantially horizontal direction above and below the hub portion 20, respectively, and a pair of left and right vertical rim portions 33 that connect end portions in the left-right direction of the upper rim portion 32 and the lower rim portion 31 (FIG. 2). The distance from the hub portion 20 to the upper rim portion 32 is longer than the distance from the hub portion 20 to the lower rim portion 31 (FIG. 2). The vertical rim portion 33 has the lower vertical rim portion 331 below the spoke portion 40 and the upper vertical rim portion 332 above the spoke portion 40 (FIG. 3). The upper vertical rim portion 332 extends in a substantially vertical direction from the spoke portion 40 to the upper rim portion 32 in a neutral state where the steering wheel 10 is not steered, and the angle θ3 of the upper vertical rim portion 332 with respect to the horizontal line is a predetermined angle or more (at least 45 degrees or more).

As described above, in the present embodiment, in a state where the distance from the hub portion 20 to the upper rim portion 32 is long, that is, in a state where the upper vertical rim portion 332 is longer than the lower vertical rim portion 331, the upper vertical rim portion 332 is raised by the predetermined angle θ3 or more with respect to the horizontal line and extended in the vertical direction. For this reason, the gripping area of the upper vertical rim portion 332 is enlarged, but gripping the upper vertical rim portion 332 (particularly, the upper portion of the upper vertical rim portion 332) against the own weight of the hand imposes a heavy burden on the occupant. As a result, the occupant grips the upper vertical rim portion 332 by supporting the lower portion of the hand with the spoke portion 40, and the actual gripping area of the steering wheel is in the vicinity of the spoke portion 40. Accordingly, the grip sensor 50 disposed on the spoke portion 40 can satisfactorily detect the grip operation of the steering wheel 10. Therefore, the cost can be suppressed without increasing the number and an installation area of sensors for detecting a gripping state.

(2) The grip sensor 50 is the grip sensor 50 of electrostatic capacitance type having the electrode 51 that is disposed on the spoke portion 40 to detect contact or proximity of the occupant with or to the rim portion 30. Accordingly, the grip sensor 50 can be configured at low cost. In addition, as described above, since the upper vertical rim portion 332 is provided to be inclined at the predetermined angle θ3 or more with respect to the horizontal line, the hand of the occupant when the steering wheel 10 is gripped is positioned in the vicinity of the spoke portion 40, and the distance from the grip sensor 50 to the hand of the occupant gripping the steering wheel 10 is less than or equal to a predetermined detectable distance. Accordingly, the grip sensor 50 can satisfactorily detect the grip operation of the rim portion 30.

(3) The electrode 51 includes the central electrode portion 511 extending in a substantially vertical direction, the lower electrode portion 512 extending, in an inclined manner, downward from the lower end portion of the central electrode portion 511 and to the lateral inside, and the upper electrode portion 513 extending, in an inclined manner, upward from the upper end portion of the central electrode portion 511 and to the lateral inside (FIG. 4A). Accordingly, the electrode 51 is provided to be enlarged in the up-down direction, and the detection area of the grip operation by the grip sensor 50 installed in the spoke portion 40 can be enlarged.

(4) The steering apparatus 100 further includes the switch (operable switch) 45 operated by the occupant (FIG. 3). The switch 45 is disposed in an area surrounded by the upper electrode portion 513, the central electrode portion 511, and the lower electrode portion 512 (FIG. 4A). Accordingly, the switch 45 is provided in the vicinity of the area where the occupant grips steering wheel 10 (the area AR20 in FIG. 2), so that the switch operation is easy.

(5) The steering apparatus 100 further includes the torque sensor 60 that detects a load acting on the steering shaft 11 in the direction of gravity, and the determination unit 71 that determines whether or not the rim portion 30 is gripped, on the basis of signals from the grip sensor 50 and the torque sensor 60 (FIG. 6A). Accordingly, the grip operation of the top portion of the steering wheel 10 in which the distance from the grip sensor 50 exceeds the detectable area can also be satisfactorily detected using the torque sensor 60. The torque sensor 60 can also detect the grip operation of portions other than the top portion and the bottom portion of the rim portion 30. Therefore, in a case where the grip sensor 50 fails, the torque sensor 60 can be used instead of the grip sensor 50 to detect the grip operation.

In the above embodiment, by extending the vertical rim portion 33 in a substantially vertical direction, the upper part of the vertical rim portion 33 is made difficult to grip, so that the occupant's hand is positioned near the grip sensor 50, but the diameter of the vertical rim portion 33 may be changed so that the occupant's hand is positioned near the grip sensor 50. Specifically, as illustrated in FIG. 3, in the upper vertical rim portion 332 having the lower-side upper vertical rim portion 332A, where the distance from the spoke portion 40 is within the detectable distance, and the upper-side upper vertical rim portion 332B, where the distance from the spoke portion 40 exceeds the detectable distance, the diameter or thickness of the upper-side upper vertical rim portion 332B may be made smaller than that of the lower-side upper vertical rim portion 332A. The upper vertical rim portion 332, which is thin in diameter or thickness, is difficult to grip. Therefore, the occupant tends to avoid gripping the upper-side upper vertical rim portion 332B, which is thin in diameter or thickness, and the grip sensor 50 arranged on the spoke portion 40 can easily detect the gripping operation of the rim portion 30.

In the above embodiment, the rim portion 30 is configured by the upper rim portion 32 (upper horizontal rim portion) and the lower rim portion 31 (lower horizontal rim portion) extending substantially horizontally above and below the hub portion 20, respectively, and a pair of left and right vertical rim portions 33 connecting the left and right ends of the upper rim portion 32 and the lower rim portion 31. More specifically, the distance from the hub portion 20 to the upper rim portion 32 is configured to be longer than the distance from the hub portion 20 to the lower rim portion 31, and the vertical rim portion 33 is provided with the lower vertical rim portion 331 (first vertical rim portion) below the spoke portion 40 and the upper vertical rim portion 332 (second vertical rim portion) above the spoke portion 40. In this regard, in the neutral state where the steering wheel 10 is not steered, if the second vertical rim portion extends in a substantially vertical direction from the spoke portion 40 to the upper horizontal rim portion and the angle of the second vertical rim portion with respect to the horizontal line is a predetermined angle or more, the configuration of the rim portion may be any.

In the above embodiment, the grip sensor 50 of electrostatic capacitance type (sensor part) is installed on the spoke portion 40 to detect the grip operation of the rim portion 30 by the occupant, but the sensor part may be installed on the hub portion 20. In addition, as the sensor part, not only the grip sensor 50 of electrostatic capacitance type but also a sensor part of another non-contact type can be used. In the above embodiment, the electrode 51 is configured by the central electrode portion 511, the lower electrode portion 512, and the upper electrode portion 513, but the shape of the electrode is not limited to the above.

In the above embodiment, the distance from the grip sensor 50 to the lower-side upper vertical rim portion 332A is set to be within the detectable distance of the grip sensor 50, but the distance to a part of the lower-side upper vertical rim portion 332A may be set to be within the detectable distance. In this case, for example, when the occupant grips the upper vertical rim portion 332 with the lower end of the hand in contact with the spoke portion 40, the position of the sensor part should be set and the second vertical rim portion should be configured so that the distance to the portion gripped by the occupant is within the detectable distance.

In the above embodiment, the upper vertical rim portion 332 is configured by the lower-side upper vertical rim portion 332A (lower second vertical rim portion) and the upper-side upper vertical rim portion 332B (upper second vertical rim portion). That is, the second vertical rim portion is approximated by a pair of straight lines L2 and L3, but it may be approximated by a single straight line or three or more straight lines. Alternatively, the second vertical rim portion may be approximated by a curve, assuming that the entire second vertical rim portion extends along a curve.

In the above embodiment, the pair of upper and lower switches 45 operated by the occupant is provided on the spoke portion 40, but the configuration of a switch part is not limited to the above configuration. However, it is preferable that the switch part is provided in the area surrounded by the electrode 51. In the above embodiment, the torque sensor 60 detects the load acting on the steering shaft 11 in the direction of gravity, but another sensor part can also be used to detect the load in the direction of gravity. Therefore, the configuration of the determination unit that determines whether the rim portion is gripped based on signals from a sensor part and another sensor part is not limited to the above configuration.

The above embodiment can be combined as desired with one or more of the above modifications. The modifications can also be combined with one another.

According to the present invention, it is possible to satisfactorily detect the grip state of an irregularly shaped steering wheel without increasing the number or installation area of sensors.

Above, while the present invention has been described with reference to the preferred embodiments thereof, it will be understood, by those skilled in the art, that various changes and modifications may be made thereto without departing from the scope of the appended claims.

What is claimed is:

1. A steering apparatus comprising:
a steering wheel including a hub portion connected to a steering shaft, a rim portion extending around the hub portion over an entire circumference in a circumferential direction centered on the hub portion so as to be gripped by an occupant, and a spoke portion extending in a left-right direction from the hub portion to connect the hub portion and the rim portion; and
a sensor part of a non-contact type provided on the hub portion or the spoke portion so as to detect a grip operation of the rim portion by the occupant, wherein
the rim portion includes an upper horizontal rim portion and a lower horizontal rim portion extending substantially horizontally above and below the hub portion, respectively, and a pair of left and right vertical rim portions connecting left and right end portions in the left-right direction of the upper horizontal rim portion and left and right end portions in the left-right direction of the lower horizontal rim portion,
a distance from the hub portion to the upper horizontal rim portion is longer than a distance from the hub portion to the lower horizontal rim portion,
the pair of left and right vertical rim portions each includes a first vertical rim portion located below the spoke portion and a second vertical rim portion located above the spoke portion, and
the second vertical rim portion extends in a substantially vertical direction from the spoke portion to the upper horizontal rim portion in a neutral state where the steering wheel is not steered, and an angle of the second vertical rim portion with respect to a horizontal line is equal to or larger than a predetermined angle.

2. The steering apparatus according to claim 1, wherein
the sensor part includes a sensor of an electrostatic capacitance type having an electrode arranged on the spoke portion so as to detect a contact or a proximity of the occupant with respect to the rim portion.

3. The steering apparatus according to claim 2, wherein
the electrode includes a central electrode portion extending in the substantially vertical direction, a lower electrode portion extending in an inclined manner downward and inward in the left-right direction from a lower end portion of the central electrode portion, and an upper electrode portion extending in an inclined manner upward and inward in the left-right direction from an upper end portion of the central electrode portion.

4. The steering apparatus according to claim 3, further comprising
a switch part operated by the occupant, wherein
the switch part is arranged in an area surrounded by the upper electrode portion, the central electrode portion, and the lower electrode portion.

5. The steering apparatus according to claim 3, wherein
the electrode includes an insulating portion configured to insulate the central electrode portion from the lower electrode portion, and to insulate the central electrode portion from the upper electrode portion.

6. The steering apparatus according to claim 1, wherein
the second vertical rim portion includes a lower second vertical rim portion and an upper second vertical rim portion, a distance from the spoke portion to the lower second vertical rim portion being an equal to or smaller than a predetermined distance, a distance from the spoke portion to the upper second vertical rim portion being larger than the predetermined distance, and
a diameter or a thickness of the upper second vertical rim portion is smaller than a diameter or a thickness of the lower second vertical rim portion.

7. The steering apparatus according to claim 1, further comprising:
another sensor part configured to detect a load in a direction of gravity acting on the steering shaft; and
an electronic control unit having a microprocessor and a memory connected to the microprocessor, wherein
the microprocessor is configured to perform
determining whether the rim portion is gripped based on signals from the sensor part and the other sensor part.

8. A vehicle including the steering apparatus according to claim 1, wherein
the vehicle is configured to switch a drive mode between a self-drive mode, in which a driving operation by a driver is unnecessary, and a manual drive mode, in which the driving operation by the driver is required,
the vehicle further comprises:
a notification part notifying the driver of a grip command of the steering wheel; and
an electronic control unit having a microprocessor and a memory connected to the microprocessor, and
the microprocessor is configured to perform
determining whether the rim portion is gripped based on signals from the sensor part when a grip request for the steering wheel is received during travel in the self-drive mode, and
controlling the notification part to notify the driver of the grip command when it is determined that the rim portion is not gripped.
